(19) United States
(12) Patent Application Publication
(10) Pub. No.: US 2008/0012634 A1
(43) Pub. Date: Jan. 17, 2008

(54) Programmable gain amplifier

(75) Inventors: Ming Oyang, Ping Tung City (TW); Meng-Jyh Lin, Hsin Chu City (TW)

Correspondence Address: BIRCH STEWART KOLASCH & BIRCH, PO BOX 747, FALLS CHURCH, VA, 22040-0747, US

(73) Assignee: Sunplus Technology Co., Ltd.

(21) Appl. No.: 11/812,742

(22) Filed: Jun. 21, 2007

(30) Foreign Application Priority Data
Jul. 12, 2006 (TW) 095125368

(51) Int. Cl. H03F 1/02

(52) U.S. Cl. 330/9

(57) ABSTRACT

A programmable gain amplifier includes an OP amplifier, N decayed capacitor(s), (N+1) adjusting capacitor modules, switches, a switch control module, and a feedback switch. First terminals of adjusting capacitors of the capacitor modules are connected together. One capacitor module is connected to an input terminal of the OP amplifier, and neighboring two of the capacitor modules are connected together through one of the decayed capacitor(s). Each switch controlled by the switch control module has a common terminal connected to a second terminal of the capacitor so as to couple the capacitor to an input signal, a reference voltage, or an output terminal of the OP amplifier. The feedback switch is connected between the output terminal and the first input terminal, and turns on in a first phase. The adjusting capacitor can be connected to the output terminal to serve as the feedback capacitance through control of the switches in a second phase, which does not overlap with the first phase.

This application claims the benefit of the filing date of Taiwan Application Ser. No. 095125368, filed on Jul. 12, 2006, the content of which is incorporated herein by reference.

### BACKGROUND OF THE INVENTION

1. Field of Invention

The invention relates to a gain amplifier, and more particularly to a programmable gain amplifier having decayed capacitors and sampling capacitors, which can be switched as feedback capacitance.

2. Related Art

FIG. 1 is a schematic illustration showing a conventional capacitors switching type amplifier 100. Referring to FIG. 1, the amplifier 100 includes a sampling capacitor C_{S}, a feedback capacitor C_{F}, two switches S1 and S2, and an OP amplifier 110. The amplifier 100 operates as follows. In a first phase (sampling phase), the sampling capacitor C_{S} is connected to an input signal Vᵢₙ by the witch S1 and the switch S2 is turned on. Thus, the sampling capacitor C_{S} is charged and the input signal Vᵢₙ is sampled in the first phase. In a second phase (amplifying phase), the sampling capacitor C_{S} is connected to a ground potential by the switch S1, and the switch S2 is turned off, so that the charges stored in the sampling capacitor C_{S} in the first phase are redistributed between the sampling capacitor C_{S} and the feedback capacitor C_{F}. Thus, an output signal Vₒᵤₜ at an output terminal of the OP amplifier 110 is generated. In general, the gain of the amplifier is determined according to a ratio of the sampling capacitor C_{S} to the feedback capacitor C_{F}.

The above-mentioned architecture cannot make a dynamic adjustment according to the desired gain. U.S. Patent Publication No. 2005/0018061 discloses a programmable gain amplifier. FIG. 2 is a schematic illustration showing a programmable gain amplifier 200 disclosed in U.S. Patent Publication No. 2005/0018061. As shown in FIG. 2, each of the capacitors C_{P0} to C_{P127} and C_{N0} to C_{N127} is selectively coupled to an input signal, an output terminal of an OP amplifier 349 or a reference voltage through a switch. The programmable gain amplifier 200 operates according to the states of each switch controlled by switch control modules 351 and 353. For example, the switch control modules 351 and 353 can decide the number of the capacitors coupled to the input signal in the first phase so as to determine the equivalent capacitance of the sampling capacitors. In addition, the switch control modules 351 and 353 also decides the number of the capacitors coupled to the OP amplifier 349 in the second phase so as to determine the equivalent capacitance of the feedback capacitors. In other words, the switch control modules 351 and 353 can control the ratio of the capacitance of the sampling capacitors to the capacitance of the feedback capacitors and equivalently control the gain of the programmable gain amplifier 200 according to the control of the switches.

In the example of the programmable gain amplifier 200 with the six-bit resolution, however, the programmable gain amplifier 200 has to support the six-bit gain control, so it must use 128*2 unit capacitors (see FIG. 2). The great number of the capacitors occupies a great area on the chip, and makes the total capacitance become a load of a previous stage of circuits, so that the high speed and low power-consumption requirements cannot be satisfied. In addition, if the programmable gain amplifier 200 has to support the higher-resolution gain control, such as seven-bit gain control, the number of the capacitors used in the programmable gain amplifier 200 has to be doubled so that 128*2*2 unit capacitors have to be used. Consequently, the higher resolution needs the more capacitors and the larger area for the capacitors under the architecture of the programmable gain amplifier 200. So, this is not a very economic solution.

Thus, U.S. Pat. No. 6,580,382 discloses another programmable gain amplifier 300 to solve the above-mentioned problems, as shown in FIG. 3. Referring to FIG. 3, the programmable gain amplifier 300 includes two capacitor arrays. Each capacitor array includes some additional capacitors and a binary weighting sector substantially divided into two stages, which are capacitively coupled together through decayed capacitors 34 and 35 so as to reduce the capacitor ratio. Because the decayed capacitors 34 and 35 are adopted, the number of the capacitors can be reduced, the area occupied by the capacitor can be reduced, and the load viewed from a previous stage of circuits can be reduced according to the serially connected effect of the capacitors.

In the programmable gain amplifier 300, however, only the capacitor C_{F} serves as a feedback capacitor. In other words, the programmable gain amplifier 300 only can control the gain by adjusting the equivalent capacitance of the sampling capacitors. Thus, it is impossible to provide diversified control mechanisms and to reduce the area occupied by the capacitor C_{F}.

### SUMMARY OF THE INVENTION

It is therefore an object of the invention to provide a programmable gain amplifier having decayed capacitors and sampling capacitors that can be switched into feedback capacitors so as to reduce the area occupied by the programmable gain amplifier.

To achieve the above-mentioned object, the invention provides a programmable gain amplifier including an OP amplifier, N decayed capacitor(s), (N+1) adjusting capacitor modules, a plurality of switches, a switch control module and a feedback switch, wherein N is a positive integer. Each of the adjusting capacitor modules has at least one adjusting capacitor. First terminals of all adjusting capacitors of each of the adjusting capacitor modules are connected together, one of the adjusting capacitor modules is connected to an input terminal of the OP amplifier, and neighboring two of the adjusting capacitor modules are connected together through one of the decayed capacitors. Each of the switches is controlled by the switch control module, and switch common terminals of the switches are respectively connected to second terminals of the adjusting capacitors. Thus, the connected adjusting capacitor can be connected to an input signal, a reference voltage, or an output terminal of the OP amplifier. The feedback switch is connected between the output terminal of the OP amplifier and the first input terminal of the OP amplifier and turns on in a first phase or otherwise turns off.

The adjusting capacitor may be connected to the output terminal of the OP amplifier to serve as a feedback capacitor in a second phase under the control of the switches, and the first phase and the second phase do not overlap with each other.

Because the programmable gain amplifier according to the invention utilizes the architecture having the decayed capacitors, the area occupied by sampling capacitors can be reduced. In addition, because the internal capacitors in the programmable gain amplifier of the invention can serve as the sampling capacitors as well as the feedback capacitors, it is possible to provide various signal gains in the aspect of signal processing, and to save the area occupied by the capacitor originally serving as the feedback capacitor.

### BRIEF DESCRIPTION OF THE DRAWINGS

FIG. 1 is a schematic illustration showing a conventional amplifier for switching between capacitors.

FIG. 2 is a schematic illustration showing a conventional programmable gain amplifier.

FIG. 3 is a schematic illustration showing another conventional programmable gain amplifier.

FIG. 4A is a schematic illustration showing a programmable gain amplifier according to a first embodiment of the invention.

FIG. 4B shows an equivalent circuit of the programmable gain amplifier of FIG. 4A in a first phase.

FIG. 4C shows an equivalent circuit of the programmable gain amplifier of FIG. 4A in a second phase.

FIG. 4D shows an equivalent circuit of the input capacitor of the programmable gain amplifier of FIG. 4A.

FIG. 5 shows an equivalent circuit of the input capacitor of the programmable gain amplifier of FIG. 4A.

FIG. 6 is a schematic illustration showing a programmable gain amplifier according to a second embodiment of the invention.

FIG. 7 is a schematic illustration showing an 8-bit programmable gain amplifier.

FIG. 8 is a schematic illustration showing operating clocks of the programmable gain amplifier of FIG. 4A.

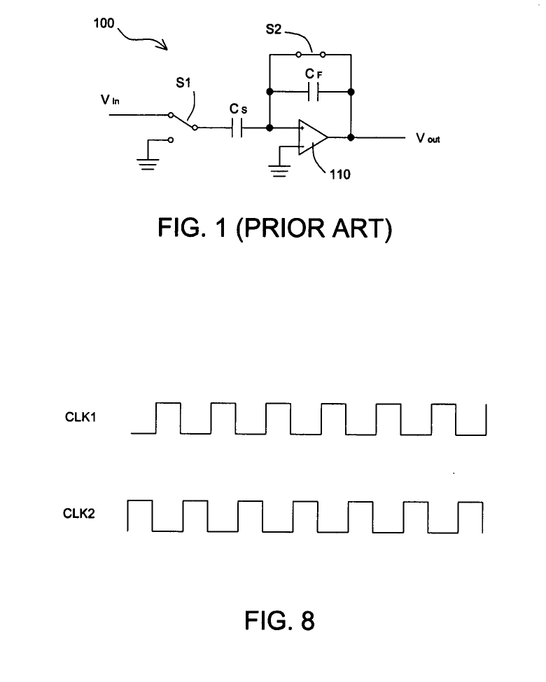

### DETAILED DESCRIPTION OF THE INVENTION

The programmable gain amplifier according to the invention will be described with reference to the accompanying drawings.

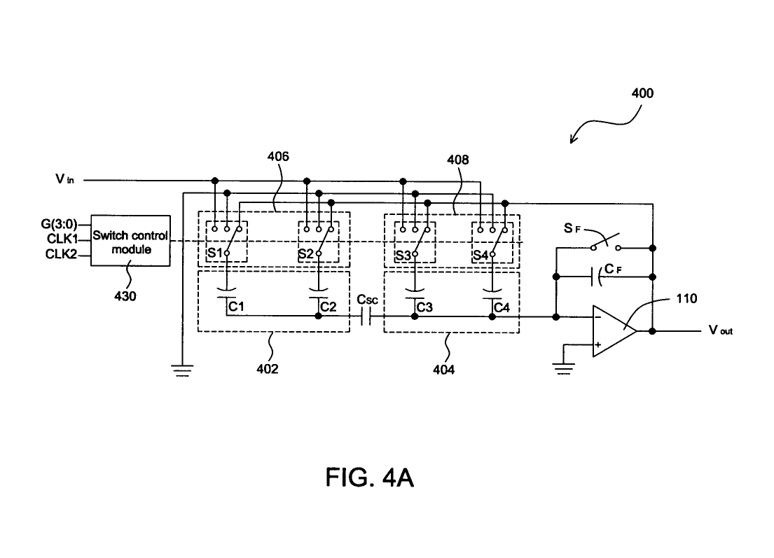

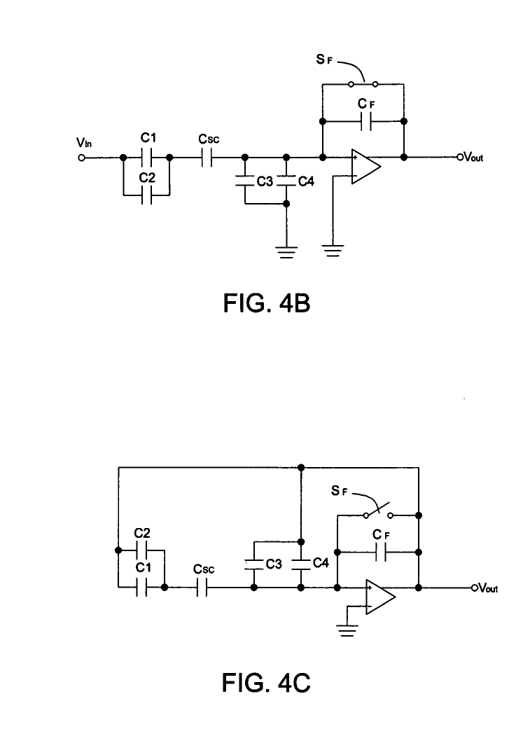

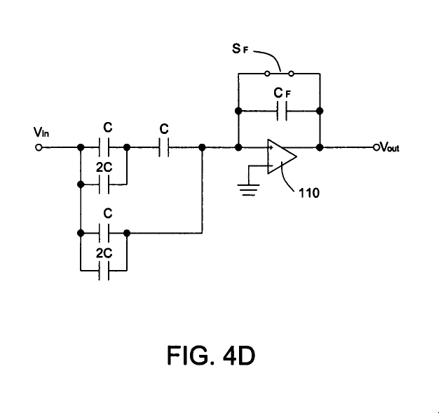

FIG. 4A is a schematic illustration showing a programmable gain amplifier 400 according to a first embodiment of the invention. In this embodiment, the programmable gain amplifier 400 is a 4-bit programmable gain amplifier. The programmable gain amplifier 400 includes an OP amplifier 110, two (N+1) adjusting capacitor modules 402 and 404, two (N+1) switch modules 406 and 408, a feedback switch S_{F}, one (N) decayed capacitor C_{SC}, one feedback capacitor C_{F} and one control module 430, wherein N is a positive integer, and N is 1 in this embodiment.

As shown in FIG. 4A, the first adjusting capacitor module 402 includes capacitors C1 and C2 having first terminals connected together. The second adjusting capacitor module 404 includes capacitors C3 and C4 having first terminals connected together. In addition, the first terminals of the first adjusting capacitor module 402 are connected to the first terminals of the second adjusting capacitor module 404 through the decayed capacitor C_{SC}. In addition, the first terminals of the second adjusting capacitor module 404 are further connected to a negative input terminal of the OP amplifier 110. The first switch module 406 includes a switch S1 having a common terminal connected to a second terminal of the capacitor C1, and a switch S2 having a common terminal connected to a second terminal of the capacitor C2. The second switch module 408 includes a switch S3 having a common terminal connected to a second terminal of the capacitor C3 and a switch S4 having a common terminal connected to a second terminal of the capacitor C4. In this embodiment, each switch has a common terminal, a first connection terminal, a second connection terminal and a third connection terminal. The first connection terminal, the second connection terminal and the third connection terminal are respectively coupled to an input signal Vᵢₙ, a grounding voltage and an output terminal Vₒᵤₜ of the OP amplifier 110.

The feedback switch S_{F} is connected between the negative input terminal and the output terminal Vₒᵤₜ of the OP amplifier 110. The control module 430 outputs a set of control signals for respectively controlling ON states of the switches S1 to S4. For example, the switches S1 to S4 can respectively selectively couple the second terminals of the adjusting capacitors C1 to C4 to the input signal Vᵢₙ, the grounding voltage, or the output terminal Vₒᵤₜ of the OP amplifier 110 under the control signals of the control module 430.

In this embodiment, in order to support the 4-bit gain control, the capacitances of the adjusting capacitors C1 and C3 are 1 C, the capacitances of the adjusting capacitors C2 and C4 are 2 C, and the capacitance of the decayed capacitor C_{SC} is also 1 C. Thus, the equivalent capacitances of the adjusting capacitors C1, C2, C3 and C4 viewed from the end of the OP amplifier 110 respectively correspond to (¼)C, (½)C, 1 C and 2 C, as shown in FIG. 4D, according to the serially connected effect of the decayed capacitor C_{SC}. In other words, the ratio of the equivalent capacitances is 1:2:4:8 (2⁰:2¹:2²:2³). Consequently, the invention can obtain the gain effect with the 4-bit resolution according to the adjusting capacitors and the proper control.

FIG. 8 is a schematic illustration showing a first phase clock CLK1 and a second phase clock CLK2 in the programmable gain amplifier 400 of FIG. 4A. As shown in FIG. 8, the programmable gain amplifier 400 operates according to two phase clocks CLK1 and CLK2. The first phase clock CLK1 is enabled (Hi state) in the first phase (sampling phase), and the second phase clock CLK2 is enabled (Hi state) in the second phase. In general, the first phase clock CLK1 and the second phase clock CLK2 are non-overlapped clocks.

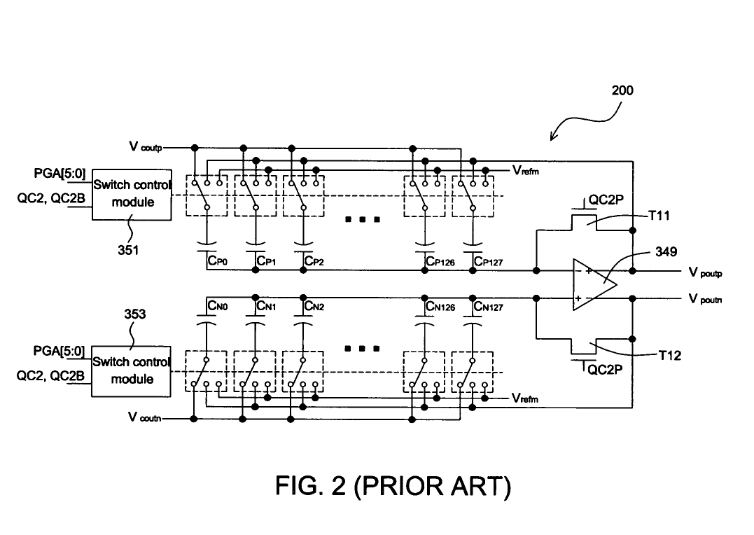

The operation of the programmable gain amplifier 400 will be described in the following. First, the switch control module 430 generates a set of control signals for respectively controlling the switches S1 to S4 according to a predetermined gain. Next, similar to the operation of the programmable gain amplifier 200 of FIG. 2, the switch control module 430 can determine one of the capacitors C1 to C4, which is coupled to the input signal Vᵢₙ in the first phase; and the switch control module 430 can determine one of the capacitors C1 to C4, which is coupled to the output terminal of the OP amplifier 110 in the second phase. In other words, the switch control module 430 can determine the equivalent capacitances of the sampling capacitor and the feedback capacitor under the controls of the switches S1 to S4. Thus, the switch control module 430 also can determine the ratio of the sampling capacitor to the feedback capacitor, and thus determine the gain of the programmable gain amplifier 400 to generate the output signal Vₒᵤₜ at the output terminal of the OP amplifier 110.

In the following description, two different operations will be illustrated to describe the operation of the programmable gain amplifier 400 in detail. The first operation is to set all the adjusting capacitors as feedback capacitors in the second phase, and the second operation is to set a portion of the adjusting capacitors as the feedback capacitors in the second phase.

FIG. 4B shows an equivalent circuit of the programmable gain amplifier of FIG. 4A in the first phase. FIG. 4C shows the equivalent circuit of the programmable gain amplifier of FIG. 4A in the second phase. That is, all the adjusting capacitors are set as the feedback capacitors.

First, as shown in FIG. 4B, the feedback switch S_{F} turns on in the first phase (i.e., the phase clock CLK1 is logic “H”). Meanwhile, the switch control module 430 generates a set of control signals for controlling the ON states of the switches S1 to S4 according to a predetermined gain. That is, the feedback switch S_{F} is controlled by the phase clock CLK1. The feedback switch S_{F} turns on when the phase clock CLK1 is logic “H”; and the feedback switch S_{F} is turned off when the phase clock CLK1 is logic “L”. According to the predetermined gain, such as G[3,0]=0011, the adjusting capacitors C1 and C2 are regarded as sampling capacitors, and the adjusting capacitors C3 and C4 are regarded as capacitors that do not work. So, the control module 430 controls the switches S1 and S2 in the first phase so that the first connection terminals thereof are connected to the common terminals thereof and the adjusting capacitors C1 and C2 are connected to the input voltage Vᵢₙ. Meanwhile, the control switches S3 and S4 connect the second connection terminals to the common terminals so that the adjusting capacitors C3 and C4 are connected to the grounding voltage. So, the input voltage Vᵢₙ charges the adjusting capacitors C1 and C2 and the decayed capacitor C_{SC} in this first phase state. That is, the adjusting capacitors C1 and C2 are serially connected to the decayed capacitor C_{SC}.

Thereafter, as shown in FIG. 4C, in the second phase (i.e., when the phase clock CLK2 is logic “H”), the feedback switch S_{F} is turned off. Meanwhile, the switch control module 430 controls the third connection terminals to be connected to the common terminals in the switches S1 to S4 in the second phase so that all the adjusting capacitors C1 to C4 are connected to the output terminal Vₒᵤₜ of the OP amplifier 110. The gain of the programmable gain amplifier 400 under the above-mentioned operation can be derived according to the rule of charge conservation:

$${V}_{in} ( G 3 * 2 C + G 2 * C + G 1 * 1 / 2 C + G 0 * 1 / 4 C ) = {V}_{out} ( 2 C + C + 1 / 2 C + 1 / 4 C + {C}_{F} )$$

$${V}_{out} = {V}_{in} ( G 3 * 2 C + G 2 * C + G 1 * 1 / 2 C + G 0 * 1 / 4 C ) / ( 2 C + C + 1 / 2 C + 1 / 4 C + {C}_{F} ) = [ G [ 3 \text{:} 0 ] C / ( 15 C + 4 {C}_{F} ) ] {V}_{in}$$

$$Gain = {V}_{out} / {V}_{in} = G ( 3 \text{:} 0 ] C / ( 15 C + 4 {C}_{F} )$$

In the equations, it is assumed that all the adjusting capacitors C1 to C4 serve as the feedback capacitors in the second phase. In the above-mentioned embodiment, the gain is 3 C/(15 C+4 C_{F}) because G[3,0]=0011.

If not all of the adjusting capacitors C1 to C4 serve as the feedback capacitors in the second phase, and only the adjusting capacitors which do not work serve as the feedback capacitors, the gain thereof may be derived according to the rule of charge conservation:

$${V}_{in} ( G 3 * 2 C + G 2 * C + G 1 * 1 / 2 C + G 0 * 1 / 4 C ) = {V}_{out} ( 2 C + C + 1 / 2 C + 1 / 4 C + {C}_{F} - ( G 3 * 2 C + G 2 * C + G 1 * 1 / 2 C + G 0 * 1 / 4 C ) ) \\ {V}_{out} = {V}_{in} ( G 3 * 2 C + G 2 * C + G 1 * 1 / 2 C + G 0 * 1 / 4 C ) / ( 2 C + C + 1 / 2 C + 1 / 4 C + {C}_{F} - G 3 * 2 C + G 2 * C + G 1 * 1 / 2 C + G 0 * 1 / 4 C ) ) = G [ 3 \text{:} 0 ] C / ( 15 C + 4 {C}_{F} - G [ 3 \text{:} 0 ] )$$

$$Gain = {V}_{out} / {V}_{in} = G [ 3 \text{:} 0 ] C / ( 15 C + 4 {C}_{F} - G [ 3 \text{:} 0 ] )$$

In the above-mentioned equation, it is assumed that not all of the adjusting capacitors C1 to C4 serve as the feedback capacitance in the second phase. In the above-mentioned embodiment, the gain is 3 C/(12 C+4 C_{F}) because G[3,0]=0011.

In addition, it is to be noted that the feedback capacitor C_{F} is an optional device. In other words, the programmable gain amplifier 400 can use its internal adjusting capacitors C1 to C4 to serve as the feedback capacitance. So, the invention may also be implemented when no feedback capacitor C_{F} is provided according to design of choice.

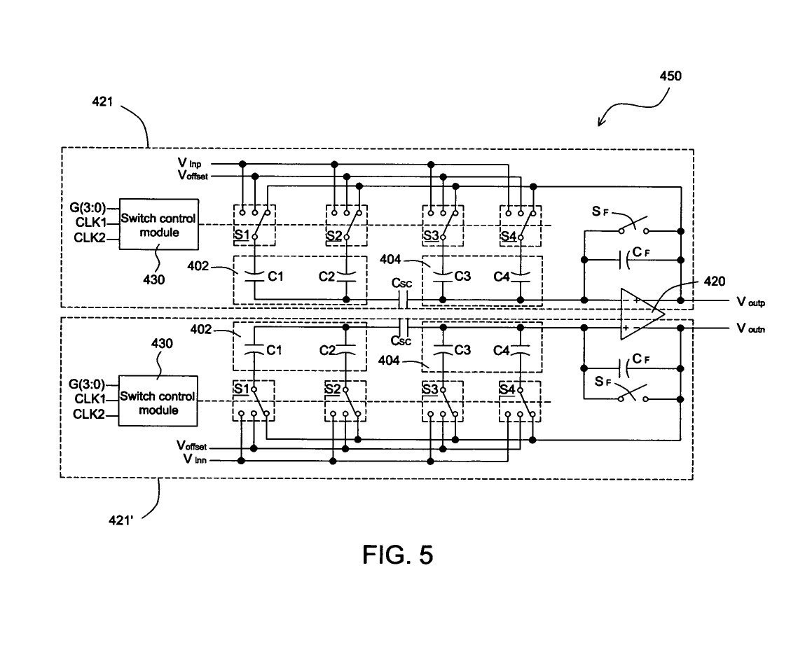

FIG. 5 is a circuit diagram showing a programmable gain amplifier 450 according to a second embodiment of the invention. The programmable gain amplifier 450 is a differential signal amplifier for receiving a pair of differential input signals Vᵢₙₚ and Vᵢₙₙ and then generating a pair of differential output signals Vₒᵤₜₚ and Vₒᵤₜₙ. The programmable gain amplifier 450 includes an OP amplifier 420 and two gain control units 421 and 421′. The architecture and the function of each of the gain control units 421 and 421′ are the same as those of the first embodiment. That is, the gain control unit 421 (421′) includes two (N+1) adjusting capacitor modules 402 and 404, two (N+1) switch modules, one feedback switch S_{F}, one (N) decayed capacitor C_{SC}, one feedback capacitor C_{F}, and one control module 430, wherein N is a positive integer and N is 1 in this embodiment. In addition, the second connection terminals of the switches S1, S2, S3 and S4 in the switch module of the programmable gain amplifier 450 according to the embodiment are connected to a reference voltage V_{offset}, which may be regarded as a common mode voltage (alternating ground voltage). Of course, it is also possible to change the reference voltage V_{offset} to the ground potential directly without departing from the spirit of the invention. Because the operation of the-programmable gain amplifier 450 is the same as that of the programmable gain amplifier 400, detailed descriptions thereof will be omitted.

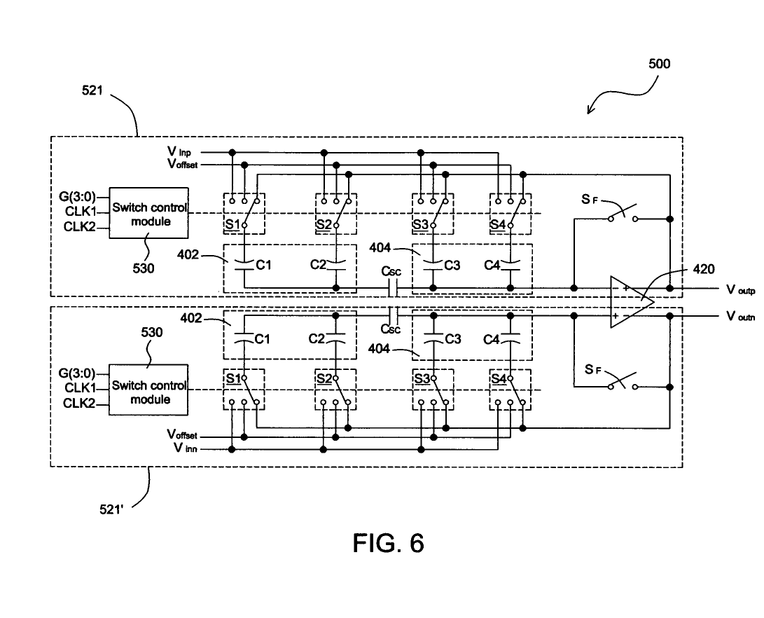

FIG. 6 is a circuit diagram showing a programmable gain amplifier 500 according to a third embodiment of the invention. The programmable gain amplifier 500 includes an OP amplifier 420 and two gain control units 521 and 521′. The programmable gain amplifier 500 of this embodiment is a differential signal amplifier, so the structures of the gain control units 521 and 521′, which are respectively connected to the positive input terminal and the negative input terminal are the same. Thus, only the gain control unit 521 is described in detail. In this embodiment, the gain control unit 521 includes two (N+1) adjusting capacitor modules, two (N+1) switch modules, one feedback switch S_{F}, one (N) decayed capacitor C_{SC}, and one control module 530. The programmable gain amplifier 500 of the third embodiment is substantially the same as the programmable gain amplifier 450 of the second embodiment except that the two gain control units 521 and 521′ in the programmable gain amplifier 500 do not include the feedback capacitor C_{F}. That is, the feedback capacitor C_{F} is omitted from the gain control units 521 and 521′. Because the programmable gain amplifier 500 and the programmable gain amplifier 450 have the same operation modes, repeated descriptions thereof will be omitted.

As shown in FIGS. 4A and 6, the programmable gain amplifier of the invention utilizes the architecture having the decayed capacitors, so the capacitor with only 14 C is needed to implement the 4-bit programmable gain amplifier. If the architecture of the programmable gain amplifier 200 of FIG. 2 is adopted, the capacitor with 30 C ((C+2 C+4 C+8 C)*2) is needed for the implementation. It is very clear that the invention reduces the number of the capacitors and the area occupied by the capacitors. In addition, under the architecture of the programmable gain amplifier 200 of FIG. 2, the load viewed from the previous stage of circuits is 15 C, and load viewed from the present invention only has the load of (15/4)C. Obviously, the invention also reduces the load. FIG. 4D shows an equivalent circuit of the programmable gain amplifier 400 of FIG. 4A, in which the first connection terminals and the common terminals of all switches are connected. As shown in this drawing, the load of the invention viewed from the previous stage of circuits is (15/4)C.

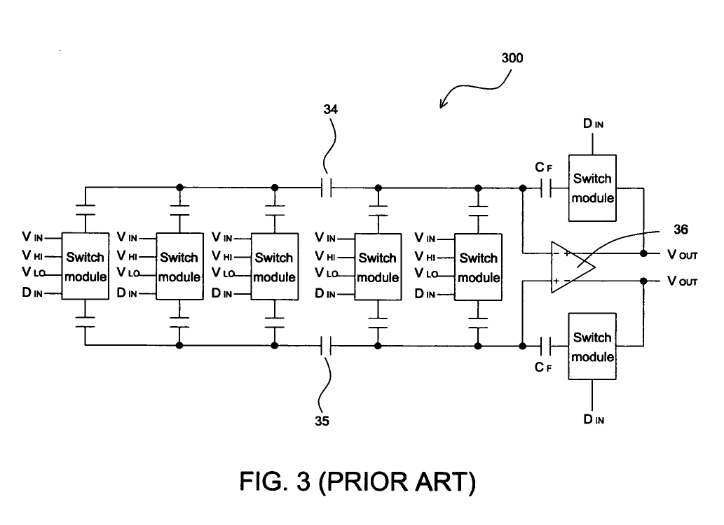

In addition, it is obtained that the invention has various operations according to the two operation methods. Compared with the architecture of the programmable gain amplifier 300 of FIG. 3, the invention can adjust the equivalent capacitance of the sampling capacitor and the equivalent capacitance of the feedback capacitor by switching the control switches. So, the invention may also be implemented without using the feedback capacitor C_{F}, the number of the capacitors is further reduced, and the more diversified control mechanisms can be provided.

It is to be noted that the 4-bit programmable gain amplifier 400 or 500 only serves as one embodiment of the invention without any limitation. In other words, the invention may also be applied to the higher-bit programmable gain amplifier. For example, the invention can utilize more decayed capacitors to reduce the number of the capacitors and the area of the overall programmable gain amplifier.

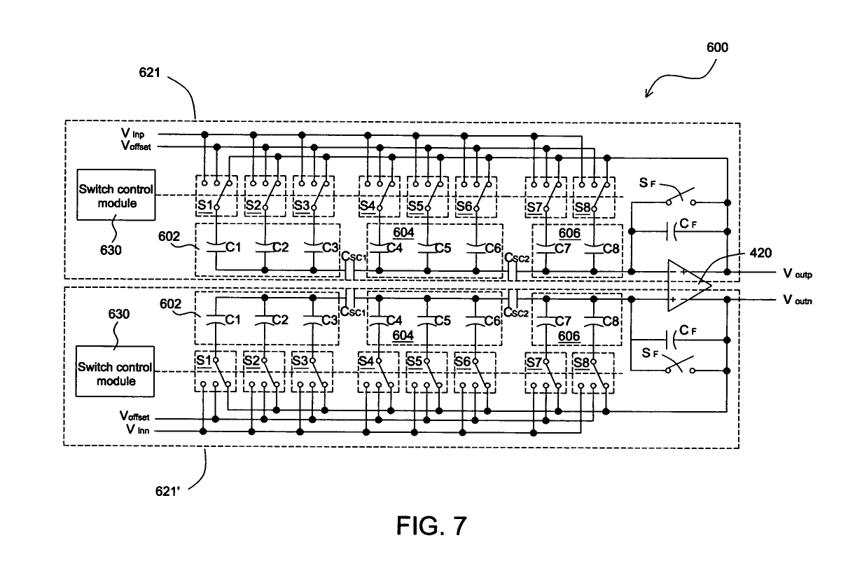

FIG. 7 is a schematic illustration showing an 8-bit programmable gain amplifier 600 according to a fourth embodiment of the invention. Referring to FIG. 7, the programmable gain amplifier 600 includes an OP amplifier 420 and two gain control units 621 and 621′. The programmable gain amplifier 600 of this embodiment is a differential signal amplifier, so the structures of the gain control units 621 and 621′, which are respectively connected to the positive input terminal and the negative input terminal, are the same. Thus, only the gain control unit 621 is described in detail. In this embodiment, the gain control unit 621 includes three (N+1) adjusting capacitor modules, three (N+1) switch modules, one feedback switch S_{F}, two (N) decayed capacitors C_{SC1} and C_{SC2}, one feedback capacitor C_{F}, and one control module 630, wherein N is a positive integer and N is 2 in this embodiment.

Referring to FIG. 7, the first adjusting capacitor module 602 includes capacitors C1, C2 and C3 having first terminals connected together; the second adjusting capacitor module 604 includes capacitors C4, C5 and C6 having first terminals connected together; and the third adjusting capacitor module 606 includes capacitors C7 and C8 having first terminals connected together. In addition, the first terminals of the first adjusting capacitor module 602 are connected to the first terminals of the second adjusting capacitor module 604 through the decayed capacitor C_{SC1}; and the first terminals of the second adjusting capacitor module 604 are connected to the first terminals of the third adjusting capacitor module 606 through the decayed capacitor C_{SC2}. In addition, the first terminals of the third adjusting capacitor module 606 are connected to an input terminal of the OP amplifier 420. The first switch module includes a switch S1 having a common terminal connected to a second terminal of the capacitor C1, a switch S2 having a common terminal connected to a second terminal of the capacitor C2, and a switch S3 having a common terminal connected to a second terminal of the capacitor C3. The second switch module includes a switch S4 having a common terminal connected to a second terminal of the capacitor C4, a switch S5 having a common terminal connected to a second terminal of the capacitor C5, and a switch S6 having a common terminal connected to a second terminal of the capacitor C6. The third switch module includes a switch S7 having a common terminal connected to a second terminal of the capacitor C7 and a switch S8 having a common terminal connected to a second terminal of the capacitor C8. In this embodiment, each switch has one common terminal, a first connection terminal, a second connection terminal and a third connection terminal, and the corresponding connection terminals of each switch are connected together. The first, second and third connection terminals are respectively coupled to an input signal Vᵢₙ, a reference voltage V_{offset}, and an output terminal Vₒᵤₜₚ of the OP amplifier 420. The reference voltage V_{offset} may be regarded as a common mode voltage (alternating ground voltage). Of course, it is also possible to change the reference voltage V_{offset} to the ground potential directly according to design of choice. This change does not depart from the spirit of the invention.

Under the circuit architecture of FIG. 7, the capacitors C1 to C8 viewed from the end of the OP amplifier respectively correspond to ( 1/64)C, ( 1/32)C, ( 1/16)C, (⅛)C, (¼)C, (½)C, C and 2 C in order to support the 8-bit operation, which will not be described because one of ordinary skill in the art may understand the associated operations.

Compared with the prior art, the programmable gain amplifier of the invention utilizes the architecture having the decayed capacitors, so the area occupied by the sampling capacitors can be reduced. In addition, because the internal capacitors in the programmable gain amplifier of the invention can serve as not only the sampling capacitors but also the feedback capacitors, various signal gains can be provided after the signal processing, and the area occupied by the original feedback capacitor can be saved.

What is claimed is:

1. A programmable gain amplifier, comprising:
an OP amplifier having a first input terminal, a second input terminal and an output terminal;
N decayed capacitors, wherein N is a positive integer;
N+1 adjusting capacitor modules, each said adjusting capacitor module having at least one adjusting capacitor having a first terminal and a second terminal, the first terminals of all the adjusting capacitors of each of the adjusting capacitor modules being connected together and defined as a capacitor module common terminal, wherein the capacitor module common terminal of one of the adjusting capacitor modules is connected to the first input terminal of the OP amplifier, and the capacitor module common terminals of neighboring two of the adjusting capacitor modules are connected together through one of the N decayed capacitors;
a plurality of switches, having a switch common terminal and a plurality of output connection terminals each, wherein the switch common terminals of the switches are respectively connected to the second terminals of the adjusting capacitors so as to couple each of the adjusting capacitors to an input signal, a reference voltage, or the output terminal of the OP amplifier;
a switch control module, for generating a set of control signals for respectively controlling the switches according to a gain control signal; and
a feedback switch, which is coupled between the output terminal and the first input terminal of the OP amplifier, and is turned on in a first phase;
wherein the adjusting capacitors may be connected to the output terminal of the OP amplifier to serve as a feedback capacitance under control of the switches in a second phase, and the first phase and the second phase do not overlap with each other;
wherein the switch control module couples one portion of the adjusting capacitors to the input signal and couples the other portion of the adjusting capacitors to the reference voltage in the first phase, and couples the adjusting capacitors, which are coupled to the input signal in the first phase, to the reference voltage, and connects the adjusting capacitors, which are coupled to the reference voltage in the first phase, to the output terminal of the OP amplifier to serve as the feedback capacitance in the second phase according to a desired gain.

2. The programmable gain amplifier according to claim 1, further comprising a feedback capacitor coupled between the output terminal and the first input terminal of the OP amplifier to serve as the feedback capacitance, wherein the feedback capacitor and the feedback switch are connected in parallel.

3. The programmable gain amplifier according to claim 1, wherein the switch control module connects the switch common terminals of all of the switches in the second phase to the output terminal of the OP amplifier to serve as the feedback capacitance.

4. The programmable gain amplifier according to claim 1, wherein N is 1, and each of the adjusting capacitor modules has two adjusting capacitors for providing the programmable gain amplifier with a 4-bit resolution.

5. The programmable gain amplifier according to claim 1, wherein N is 2, the two adjusting capacitor modules have three adjusting capacitors, and the adjusting capacitor module connected to the input terminal of the OP amplifier has two adjusting capacitors so as to provide the programmable gain amplifier with an 8-bit resolution.

6. A programmable gain amplifier, comprising:
a differential OP amplifier, having a set of differential input terminals and a set of differential output terminals; and
two gain control units, each said gain control unit respectively connected to one of the differential input terminals and the corresponding differential output terminal;
wherein each the gain control units comprises:
N decayed capacitor(s), wherein N is a positive integer;
N+1 adjusting capacitor modules, having at least one adjusting capacitor each, the at least one adjusting capacitor having a first terminal and a second terminal, the first terminals of all the adjusting capacitors of each of the adjusting capacitor modules being connected together and defined as a capacitor module common terminal, wherein the capacitor module common terminal of one of the adjusting capacitor modules is connected to the differential input terminal of the OP amplifier, and the capacitor module common terminals of neighboring two of the adjusting capacitor modules are connected together through one of the N decayed capacitors;
a plurality of switches, having a switch common terminal and a plurality of output connection terminals each, wherein the switch common terminals of the switches are respectively connected to the second terminals of the adjusting capacitors so as to couple each of the adjusting capacitors to an input signal, a reference voltage, or the differential output terminal of the OP amplifier;
a switch control module, for generating a set of control signals for respectively controlling the switches according to a gain control signal; and
a feedback switch, which is coupled between the output terminal and the differential input terminal of the OP amplifier, and is turned on in a first phase;
wherein the adjusting capacitors may be connected to the output terminal of the OP amplifier to serve as a feedback capacitance under control of the switches in a second phase, and the first phase and the second phase do not overlap with each other;
wherein the switch control module couples one portion of the adjusting capacitors to the input signal and couples the other portion of the adjusting capacitors to the reference voltage in the first phase, and couples the adjusting capacitors, which are coupled to the input signal in the first phase, to the reference voltage, and connects the adjusting capacitors, which are coupled to the reference voltage in the first phase, to the differential output terminal of the OP amplifier to serve as the feedback capacitance in the second phase according to a desired gain.

7. The programmable gain amplifier according to claim 6, wherein each of the gain control units further comprises a feedback capacitor to serve as the feedback capacitance, and the feedback capacitor and the feedback switch are connected in parallel.

8. The programmable gain amplifier according to claim 6, wherein the switch control module connects the switch common terminals of all of the switches to the differential output terminal of the OP amplifier to serve as the feedback capacitance in the second phase.

9. The programmable gain amplifier according to claim 6, wherein N is 1, and each of the adjusting capacitor modules has two adjusting capacitors for providing the programmable gain amplifier with a 4-bit resolution.

10. The programmable gain amplifier according to claim 6, wherein N is 2, the two adjusting capacitor modules have three adjusting capacitors, and the adjusting capacitor module connected to the differential input terminal of the OP amplifier has two adjusting capacitors so as to provide the programmable gain amplifier with an 8-bit resolution.

11. A programmable gain amplifier, comprising:
an OP amplifier having a first input terminal, a second input terminal, and an output terminal;
a decayed capacitor;
two adjusting capacitor modules, having two adjusting capacitors each, each the adjusting capacitors having a first terminal and a second terminal, the first terminals of all the adjusting capacitors of each of the adjusting capacitor modules being connected together and defined as a capacitor module common terminal, wherein the capacitor module common terminal of one of the adjusting capacitor modules is connected to the first input terminal of the OP amplifier, and the capacitor module common terminals of the two adjusting capacitor modules are connected together through the decayed capacitor;
four switches, having a switch common terminal and a plurality of output connection terminals each, wherein the switch common terminals of the switches are respectively connected to the second terminals of the adjusting capacitors so as to couple each of the adjusting capacitors to an input signal, a reference voltage, or the output terminal of the OP amplifier;
a switch control module for generating a set of control signals for respectively controlling the switches according to a gain control signal; and
a feedback switch, which is coupled between the output terminal and the first input terminal of the OP amplifier, and is turned on in a first phase;
wherein the adjusting capacitors are connected to the output terminal of the OP amplifier to serve as a feedback capacitance under control of the switches in a second phase, and the first phase and the second phase do not overlap with each other;
wherein the switch control module couples one portion of the adjusting capacitors to the input signal and couples the other portion of the adjusting capacitors to the reference voltage in the first phase, and couples the adjusting capacitors, which are coupled to the input signal in the first phase, to the reference voltage, and connects the adjusting capacitors, which are coupled to the reference voltage in the first phase, to the output terminal of the OP amplifier to serve as the feedback capacitance in the second phase according to a desired gain.

12. The programmable gain amplifier according to claim 11, further comprising a feedback capacitor to serve as the feedback capacitance, wherein the feedback capacitor and the feedback switch are connected in parallel.

13. The programmable gain amplifier according to claim 11, wherein the switch control module connects the switch common terminals of all of the switches in the second phase to the output terminal of the OP amplifier to serve as the feedback capacitance.

14. A programmable gain amplifier, comprising:
a differential OP amplifier having a set of differential input terminals and a set of differential output terminals; and
two gain control units, each said gain control unit being connected to one of the differential input terminals and the corresponding differential output terminal;
wherein each the gain control units comprises:
a decayed capacitor;
two adjusting capacitor modules, having two adjusting capacitors each, the adjusting capacitors having a first terminal and a second terminal each, the first terminals of all the adjusting capacitors of each of the adjusting capacitor modules being connected together and defined as a capacitor module common terminal, wherein the capacitor module common terminal of one of the adjusting capacitor modules is connected to the differential input terminal of the OP amplifier, and the capacitor module common terminals of neighboring two of the adjusting capacitor modules are connected together through the decayed capacitor;
four switches, having a switch common terminal and a plurality of output connection terminals each, wherein the switch common terminals of the switches are respectively connected to the second terminals of the corresponding adjusting capacitors so as to couple each of the adjusting capacitors to an input signal, a reference voltage, or the differential output terminal of the OP amplifier;
a switch control module for generating a set of control signals for respectively controlling ON states of the switches according to a gain control signal; and
a feedback switch, which is coupled between the output terminal and the differential input terminal of the OP amplifier, and is turned on in a first phase;
wherein the adjusting capacitor is connected to the output terminal of the OP amplifier to serve as a feedback capacitance under control of the switches in a second phase, and the first phase and the second phase do not overlap with each other;
wherein the switch control module couples one portion of the adjusting capacitors to the input signal and couples the other portion of the adjusting capacitors to the reference voltage in the first phase, and couples the adjusting capacitors, which are coupled to the input signal in the first phase, to the reference voltage, and connects the adjusting capacitors, which are coupled to the reference voltage in the first phase, to the output terminal of the OP amplifier to serve as the feedback capacitance in the second phase according to a desired gain.

15. The programmable gain amplifier according to claim 14, wherein each of the gain control units further comprises a feedback capacitor to serve as the feedback capacitance, and the feedback capacitor and the feedback switch are connected in parallel.

16. The programmable gain amplifier according to claim 14, wherein the switch control module connects the switch common terminals of all the switches to the differential output terminal of the OP amplifier to serve as the feedback capacitance in the second phase.

17. A programmable gain amplifier, comprising:
a differential OP amplifier having a differential input terminal and a differential output terminal; and
two gain control units, being respectively connected to the differential input terminal and the corresponding differential output terminal;
wherein each the gain control units comprises:
two decayed capacitors;
first to third adjusting capacitor modules, wherein each of the first adjusting capacitor module and the second adjusting capacitor module has three adjusting capacitors, and the third adjusting capacitor module has two adjusting capacitors, each said adjusting capacitor having a first terminal and a second terminal, the first terminals of all the adjusting capacitors of each of the first to third adjusting capacitor modules are connected together and defined as a capacitor module common terminal, the capacitor module common terminal of the third adjusting capacitor module is connected to the differential input terminal of the OP amplifier, and the capacitor module common terminals of neighboring two of the adjusting capacitor modules are connected together through one of the decayed capacitors;
eight switches, having a switch common terminal and a plurality of output connection terminals each, wherein the switch common terminals of the switches are respectively connected to the second terminals of the corresponding adjusting capacitors so as to couple each of the adjusting capacitors to an input signal, a reference voltage, or the differential output terminal of the OP amplifier;
a switch control module for generating a set of control signals for respectively controlling ON states of the switches according to a gain control signal; and
a feedback switch, which is coupled between the output terminal and the differential input terminal of the OP amplifier, and is turned on in a first phase;
wherein the adjusting capacitor may be connected to the output terminal of the OP amplifier to serve as a feedback capacitance under control of the switches in a second phase, and the first phase and the second phase do not overlap with each other.

18. The programmable gain amplifier according to claim 17, wherein each the gain control units further comprises a feedback capacitor to serve as the feedback capacitance, the feedback capacitor and the feedback switch are connected in parallel.

19. The programmable gain amplifier according to claim 17, wherein the switch control module connects the switch common terminals of all the switches to the differential output terminal of the OP amplifier in the second phase to serve as the feedback capacitance.

20. The programmable gain amplifier according to claim 17, wherein the switch control module couples one portion of the adjusting capacitors to the input signal and couples the other portion of the adjusting capacitors to the reference voltage in the first phase, and couples the adjusting capacitors, which are coupled to the input signal in the first phase, to the reference voltage, and connects the adjusting capacitors, which are coupled to the reference voltage in the first phase, to the differential output terminal of the OP amplifier to serve as the feedback capacitance in the second phase according to a desired gain.
